(19) United States
(12) Patent Application Publication
(10) Pub. No.: US 2011/0155206 A1
(43) Pub. Date: Jun. 30, 2011

(54) SOLAR TILE STRUCTURE AND COMBINATION THEREOF

(76) Inventors: Shih-Wei Lee, Kaohsiung County (TW); Tien-Hsing Liang, Taipei City (TW); Chi-Hung Hou, Taipei City (TW); Chen-Hai Chiu, Hsinchu County (TW); Chiu-An Tseng, Kaohsiung County (TW)

(21) Appl. No.: 12/979,263

(22) Filed: Dec. 27, 2010

(30) Foreign Application Priority Data
Dec. 30, 2009 (TW) 098145969

(51) Int. Cl. H01L 31/042; E04D 13/18

(52) U.S. Cl. 136/244; 126/622

(57) ABSTRACT

A solar tile structure includes a solar panel and a base. The solar panel is supported on an upper surface of the base. A protruding portion is formed on a lateral surface of a first short side of the base, a sunken portion is formed on a lateral surface of a second short side of the base, and the protruding portion of the first short side can be engaged with the sunken portion of the second short side tightly. The second short side of the base and a lateral side of the protruding portion substantially align with two lateral sides of the solar panel.

### BACKGROUND OF THE INVENTION

1. Field of the Invention

The present invention relates to a solar tile structure and a combination thereof, and more particularly, to a solar tile structure without rims on the short sides for preferred aesthetic appearance and a combination thereof.

2. Description of the Prior Art

Please refer to FIG. 1. FIG. 1 is a diagram of a solar panel combination 10 in the prior art. The conventional solar panel combination 10 includes a supporter 12, at least one bridging component 14, and at least one solar panel 16 disposed on the supporter 12. As shown in FIG. 1, the two bridging components 14 are disposed on two lateral sides of the supporter 12, so that the two solar panels 16 can be respectively fixed on the supporter 12 by the bridging components 14 for forming the solar panel combination 10 with a large size. Generally, the supporter 12 is utilized to be a basic framework of the solar panel combination 10, and the bridging components 14 are installed on predetermined positions of the supporter 12, so that the solar panels 16 can be combined together for forming the solar panel combination 10 according to mechanical design of the supporter 12. Due to different materials and different colors of the supporter 12, the bridging component 14, and the solar panel 16, the solar panel combination 10 shows latticed patterns of the supporter 12 between the adjacent solar panels 16 when the plurality of solar panels 16 is installed on the supporter 12. Therefore, the conventional solar panel combination 10 looks like a block array resulting in a low utilization ratio and inaesthetic appearance of the solar panel 16. Thus, design of a supporting structure for supporting the solar panels with a high utilization ratio and preferred aesthetic appearance of the solar panels is an important issue in the building material industry.

### SUMMARY OF THE INVENTION

The present invention provides a solar tile structure without rims on short sides for preferred aesthetic appearance and a combination thereof for solving above drawbacks.

According to the claimed invention, a solar tile structure includes a solar panel and a base. An upper surface of the base is for supporting the solar panel, a protruding portion is formed on a lateral surface of a first short side of the base, a sunken portion is formed on a lateral surface of a second short side of the base, and the protruding portion of the first short side and the sunken portion of the second short side are structural portions capable of wedging with each other tightly. The second short side of the base and a lateral side of the protruding portion substantially align with two lateral sides of the solar panel.

According to the claimed invention, a solar tile structure combination includes a first solar tile structure and a second solar tile structure connected to the first solar tile structure. The first solar tile structure includes a first solar panel and a first base. An upper surface of the first base is for supporting the first solar panel, a first protruding portion is formed on a lateral surface of a first short side of the first base, a first sunken portion is formed on a lateral surface of a second short side of the first base, and the first protruding portion of the first short side and the first sunken portion of the second short side are structural portions capable of wedging with each other tightly. The second short side of the first base and a lateral side of the first protruding portion substantially align with two lateral sides of the first solar panel. The second solar tile structure includes a second solar panel and a second base. An upper surface of the second base is for supporting the second solar panel, a second protruding portion is formed on a lateral surface of a third short side of the second base, a second sunken portion is formed on a lateral surface of a fourth short side of the second base, and the second protruding portion of the third short side and the second sunken portion of the fourth short side are structural portions capable of wedging with each other tightly. The fourth short side of the second base and a lateral side of the second protruding portion substantially align with two lateral sides of the second solar panel. The first protruding portion of the first solar tile structure is wedged with the corresponding second sunken portion of the second solar tile structure tightly, or the second protruding portion of the second solar tile structure is wedged with the corresponding first sunken portion of the first solar tile structure tightly when the second solar tile structure is connected to the first solar tile structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a solar panel combination in the prior art.

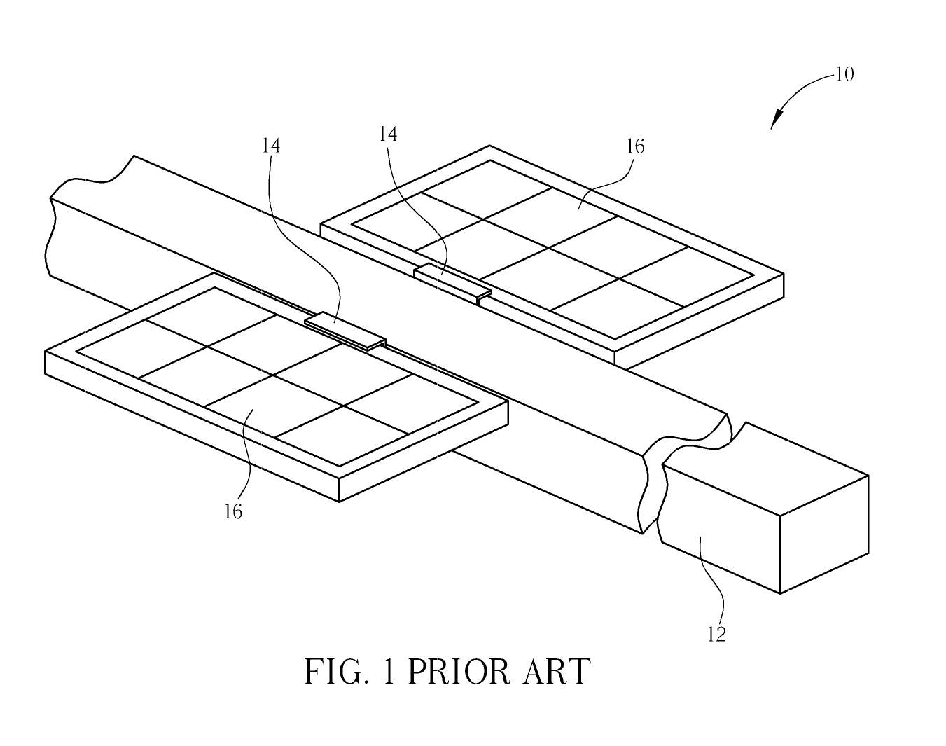

FIG. 2 is a diagram of a first solar tile structure according a preferred embodiment of the present invention.

FIG. 3 is an exploded diagram of a solar tile structure combination according the preferred embodiment of the present invention.

FIG. 4 is an assembly diagram of the solar tile structure combination according the preferred embodiment of the present invention.

FIG. 5 is a front view of the solar tile structure combination according to the preferred embodiment of the present invention.

FIG. 6 is a lateral view of the solar tile structure combination according to the preferred embodiment of the present invention.

### DETAILED DESCRIPTION

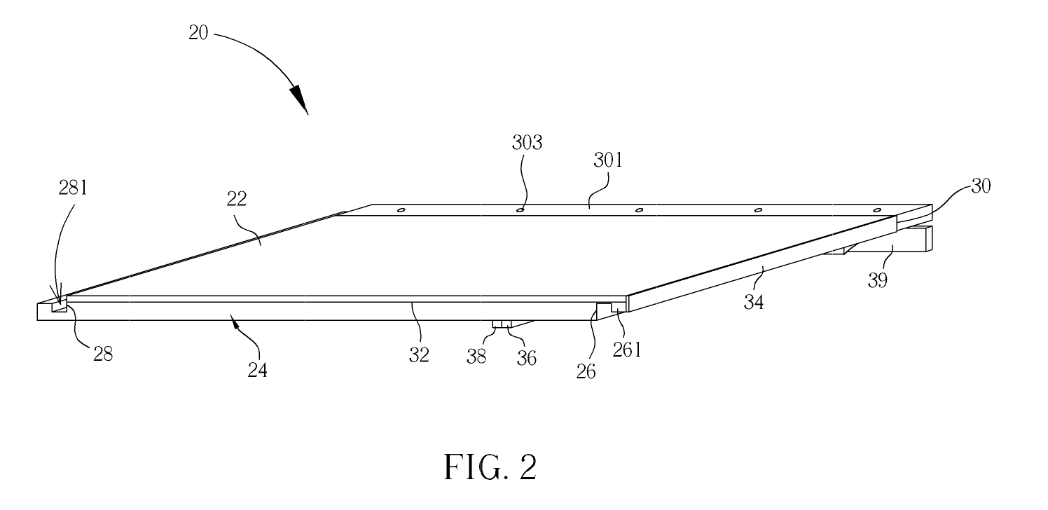

Please refer to FIG. 2. FIG. 2 is a diagram of a first solar tile structure 20 according a preferred embodiment of the present invention. The first solar tile structure 20 includes a first solar panel 22 and a first base 24. The first solar panel 22 is disposed on an upper surface of the first base 24 by gluing, lucking, or wedging methods, and so on. A first protruding portion 261 is formed on a lateral surface of a first short side 26 of the first base 24, and a first sunken portion 281 is formed on a lateral surface of a second short side 28 of the first base 24. The first protruding portion 261 can be a resilient hook, and the first sunken portion 281 can be a slot corresponding to the first protruding portion 261, so that the first protruding portion 261 on the first short side 26 and the first sunken portion 281 on the second short side 28 are capable of wedging with each other tightly, and the first solar tile structure 20 can be connected to the other solar tile structure in X direction for forming a solar panel combination with a large size. A lateral side of the first protruding portion 261 and the second short side 28 of the first base 24 respectively align with two lateral edges of the first solar panel 22, substantially, so that the first solar tile structure 20 does not have rims formed on the short sides. Besides, a rim 301 can be disposed on a first long side 30 (or a second long side 32) of the first base 24 for connecting to the other solar tile structure in Y direction substantially perpendicular to X direction. A plurality of fixing portions 303 can be disposed on the rim 301 for fixing the first base 24 on the other solar tile structure. For example, the fixing portions 303 can lock the first base 24 on the other solar tile structure.

The first solar tile structure 20 can further include a plurality of buffers 34 disposed on the lateral surfaces of the first short side 26 and the second short side 28 of the first base 24, respectively. The buffers 34 can be made of water-proofing material, which not only can prevent the first solar tile structure 20 from impacting by external force but also can prevent liquid from leaking into a gap between the first solar tile structure 20 and the other solar tile structure. The lateral surfaces of the first long side 30 and the second long side 32 can be horizontal surfaces so as to align the lateral edge of the first base 24 with the lateral edge of the first solar panel 22. In addition, the first short side 26 of the first base 24 can be parallel to the second short side 28 substantially, and the first long side 30 of the first base 24 can be parallel to the second long side 32 substantially, so that the first solar tile structure 20 can be a quadrilateral structure for connecting to other structures as an array. Shape of the first solar tile structure 20 is not limited to the above-mentioned embodiment and depends on actual demand. Furthermore, the first solar tile structure 20 can further include a transmission cable (not shown in figures), a junction box 36 disposed on a bottom surface of the first base 24, and a battery module 38 electrically connected to the junction box 36. The transmission cable can pass through the first base 24, and two ends of the transmission cable are electrically connected to the first solar panel 22 and the junction box 36, so as to transmit electricity transformed by the first solar panel 22 to the junction box 36, and then the battery module 38 can store the electricity received by the junction box 36. The first solar tile structure 20 can further include a fixing component 39 disposed on the bottom surface of the first base 24. When the first solar tile structure 20 is laid on a housetop of a building, the fixing component 39 can be wedged with a fixing point of the housetop for installing the first solar tile structure 20 on the housetop of the building stably.

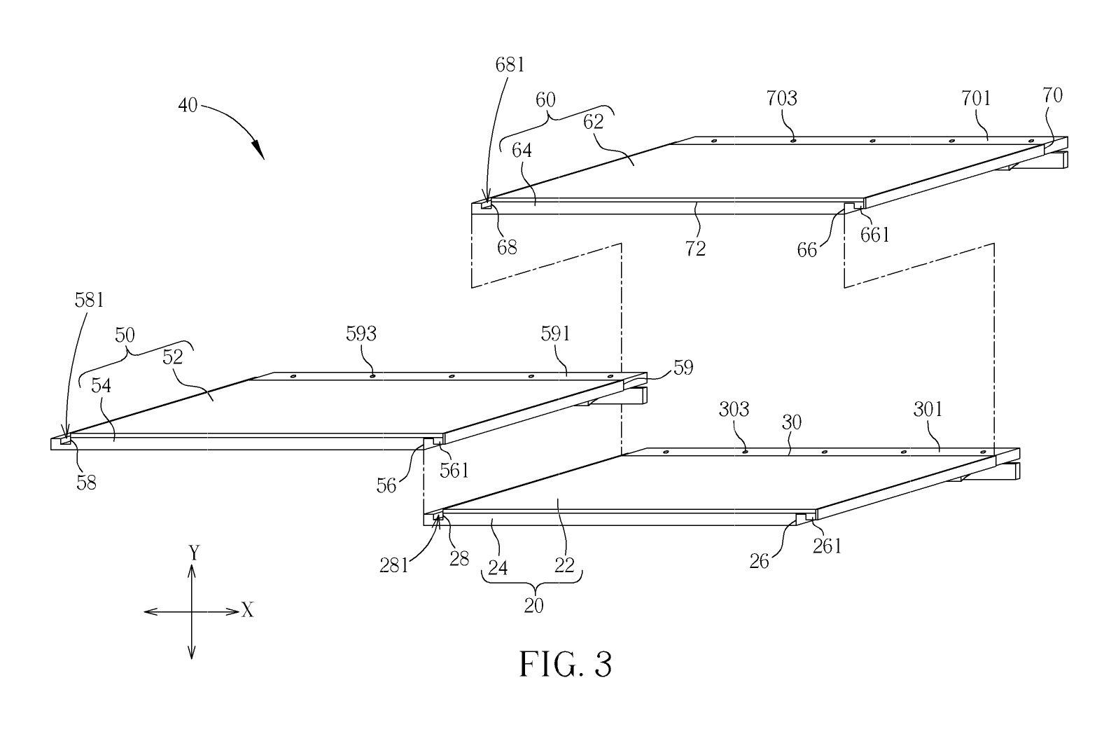

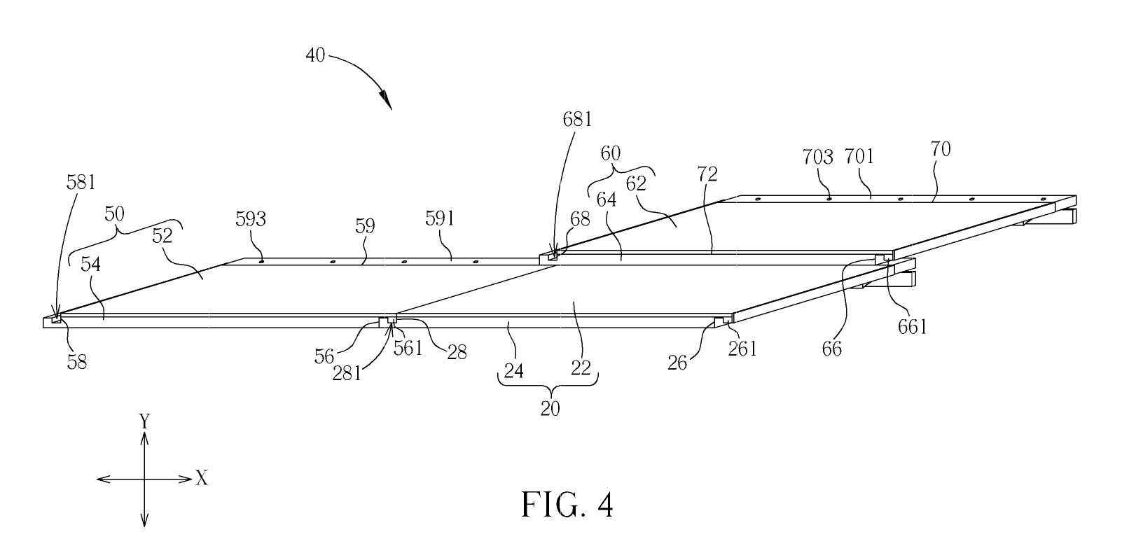

Please refer to FIG. 3 and FIG. 4. FIG. 3 is an exploded diagram of a solar tile structure combination 40 according the preferred embodiment of the present invention. FIG. 4 is an assembly diagram of the solar tile structure combination 40 according the preferred embodiment of the present invention. The solar tile structure combination 40 includes the first solar tile structure 20, a second solar tile structure 50, and a third solar tile structure 60. The second solar tile structure 50 and the third solar tile structure 60 have the same structural design and the same function as the first solar tile structure 20. As shown in FIG. 3, the second solar tile structure 50 includes a second solar panel 52 and a second base 54. The second solar panel 52 is disposed on an upper surface of the second base 54. A second protruding portion 561 is formed on a lateral surface of a third short side 56 of the second base 54, a second sunken portion 581 is formed on a lateral surface of a fourth short side 58 of the second base 54, and the second protruding portion 561 of the third short side 56 and the second sunken portion 581 of the fourth short side 58 are capable of wedging with each other tightly. The third short side 581 of the second base 54 and a lateral edge of the second protruding portion 561 respectively align with two edges of the second solar panel 52, substantially, so that the second solar tile structure 50 does not have rims formed on the short sides. The first solar tile structure 20 can be connected to the second solar tile structure 50 in X direction tightly by wedging the first sunken portion 281 of the first base 24 with the corresponding second protruding portion 561 of the second base 24, or by wedging the first protruding portion 261 of the first base 24 with the corresponding second sunken portion 581 of the second base 54. Besides, a rim 591 can be formed on a third long side 59 of the second base 54 for connecting to the other solar tile structure in Y direction. A plurality of fixing portions 593 can be disposed on the rim 591 for fixing the second base 54 on the other solar tile structure tightly. For example, the fixing portions 593 can lock the second base 54 on the other solar tile structure.

As shown in FIG. 3 and FIG. 4, the third solar tile structure 60 includes a third solar panel 62 and a third base 64. The third solar panel 62 is disposed on an upper surface of the third base 64. A third protruding portion 661 is formed on a lateral surface of a fifth short side 66 of the third base 64, a third sunken portion 681 is formed on a lateral surface of a sixth short side 68 of the third base 64, and the sixth short side 68 of the third base 64 and a lateral edge of the third protruding portion 661 respectively align with two edges of the third solar panel 62, substantially, so that the third solar tile structure 60 does not have rims on the short sides and can be connected to the other solar tile structure in X direction. Besides, a rim 701 can be formed on a fifth long side 70 of the third base 64 for connecting to the other solar tile structure in Y direction. A plurality of fixing portions 703 can be disposed on the rim 701 for fixing the third base 64 on the other solar tile structure tightly. For example, the fixing portions 703 can lock the third base 64 on the other solar tile structure. Thus, when the first solar tile structure 20 is connected to the third solar tile structure 60 via the rim 301 in Y direction, as shown in FIG. 4, the third base 64 of the third solar tile structure 60 overlaps the rim 301 of the first solar tile structure 20, the plurality of fixing portions 303 of the rim 301 can tightly engage with corresponding fixing portions (not shown in figures) on the bottom of the third base 64, and a sixth long side 72 of the third solar panel 62 substantially aligns with the first long side 30 of the first solar tile structure 20, so that the first solar tile structure 20 can be connected to the third solar tile structure 60 in Y direction tightly.

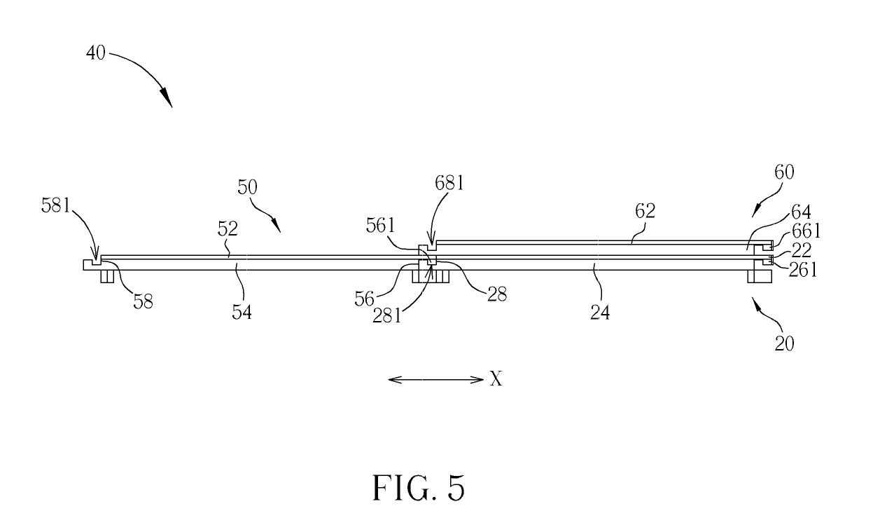

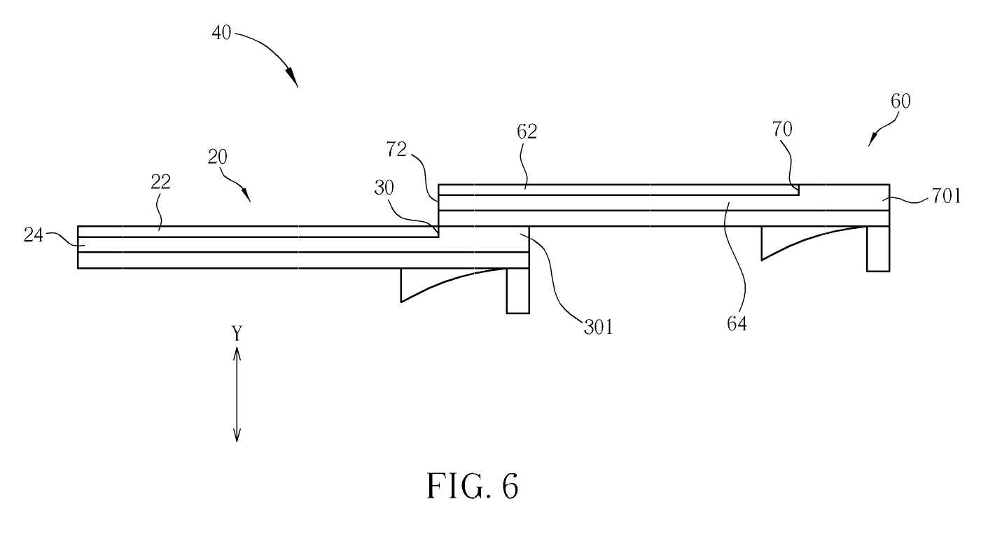

Please refer to FIG. 5 and FIG. 6. FIG. 5 is a front view of the solar tile structure combination 40 according to the preferred embodiment of the present invention. FIG. 6 is a lateral view of the solar tile structure combination 40 according to the preferred embodiment of the present invention. As shown in FIG. 5, when the first sunken portion 281 of the first solar tile structure 20 is wedged with the corresponding second protruding portion 561 of the second solar tile structure 50, the second solar panel 52 of the second solar tile structure 50 contacts against the first solar panel 22 of the first solar tile structure 20 tightly, so that the solar tile structure combination 40 has a continuous faying plane between the adjacent solar panels in X direction. As shown in FIG. 6, when the third base 64 of the third solar tile structure 60 overlaps the rim 301 of the first solar tile structure 20, the sixth long side 72 of the third solar tile structure 60 substantially aligns with the first long side 30 of the first solar tile structure 20, so that the continuous faying plane between the first solar panel 22 of the first solar tile structure 20 and the third solar panel 62 of the third solar tile structure 60 are viewed from an upper of the solar tile structure combination 40. Therefore, when assembling a plurality of solar tile structures for forming the solar tile structure combination 40, the solar tile structure combination 40 has the continuous faying planes between the adjacent solar panels in X direction and in Y direction simultaneously.

When a user intends to utilize the plurality of solar tile structures to form the solar tile structure combination 40, the adjacent solar tile structures can easily be wedged with each other in X direction by the corresponding protruding portion and the corresponding sunken portion, respectively. For example, the first sunken portion 281 of the first solar tile structure 20 can be wedged with the second protruding portion 561 of the second solar tile structure 50. The adjacent solar tile structures can easily be overlapped to each other in Y direction by the base and the corresponding rim. For example, the third base 64 of the third solar tile structure 60 can overlap the rim 301 of the first solar tile structure 20. Thus, the solar tile structure combination 40 has the continuous faying plane between the adjacent solar panels in appearance, and each base of the solar tile structure is hidden under the corresponding solar panel, so that the solar tile structure and the combination thereof of the present invention has preferred aesthetic appearance and high utilization ratio of the solar panels.

Comparing to the prior art, the solar tile structure and the related combination of the present invention utilizes the base to support the solar panel, and further utilizes the protruding portion and the sunken portion respectively formed on the lateral surfaces of the adjacent bases for connecting the adjacent solar tile structures, so that each base of the solar tile structure can be hidden under the corresponding solar panel for presenting the appearance of the continuous faying solar panels. The solar tile structure combination of the present invention with preferred aesthetic appearance not only can be assembled easily, but also has high utilization ratio of the solar panels for increasing operating efficiency of the solar energy.

Those skilled in the art will readily observe that numerous modifications and alterations of the device and method may be made while retaining the teachings of the invention.

What is claimed is:

1. A solar tile structure comprising:
a solar panel; and
a base, an upper surface of the base being for supporting the solar panel, a protruding portion being formed on a lateral surface of a first short side of the base, a sunken portion being formed on a lateral surface of a second short side of the base, and the protruding portion of the first short side and the sunken portion of the second short side being structural portions capable of wedging with each other tightly;
wherein the second short side of the base and a lateral side of the protruding portion substantially align with two lateral sides of the solar panel.

2. The solar tile structure of claim 1, wherein the protruding portion is a resilient hook, and the sunken portion is a slot corresponding to the resilient hook.

3. The solar tile structure of claim 1, wherein the first short side of the base is parallel to the second short side substantially.

4. The solar tile structure of claim 1, wherein a rim is formed on a first long side of the base.

5. The solar tile structure of claim 4, wherein lateral surfaces of the first long side and a second long side of the base are horizontal surfaces respectively.

6. The solar tile structure of claim 4, wherein the first long side of the base is parallel to the second long side substantially.

7. The solar tile structure of claim 4 further comprising:
a plurality of buffers disposed on the lateral surfaces of the first short side and the second short side of the base respectively.

8. The solar tile structure of claim 1 further comprising:
a junction box disposed on a bottom surface of the base; and
a transmission cable, two ends of the transmission cable being electrically connected to the solar panel and the junction box for transmitting electricity transformed by the solar panel to the junction box.

9. The solar tile structure of claim 8 further comprising:
a battery module electrically connected to the junction box for storing the electricity received by the junction box.

10. A solar tile structure combination comprising:
a first solar tile structure comprising:
a first solar panel; and
a first base, an upper surface of the first base being for supporting the first solar panel, a first protruding portion being formed on a lateral surface of a first short side of the first base, a first sunken portion being formed on a lateral surface of a second short side of the first base, and the first protruding portion of the first short side and the first sunken portion of the second short side being structural portions capable of wedging with each other tightly, wherein the second short side of the first base and a lateral side of the first protruding portion substantially align with two lateral sides of the first solar panel;
a second solar tile structure connected to the first solar tile structure, the second solar tile structure comprising:
a second solar panel; and
a second base, an upper surface of the second base being for supporting the second solar panel, a second protruding portion being formed on a lateral surface of a third short side of the second base, a second sunken portion being formed on a lateral surface of a fourth short side of the second base, and the second protruding portion of the third short side and the second sunken portion of the fourth short side being structural portions capable of wedging with each other tightly, wherein the fourth short side of the second base and a lateral side of the second protruding portion substantially align with two lateral sides of the second solar panel;
wherein the first protruding portion of the first solar tile structure is wedged with the corresponding second sunken portion of the second solar tile structure tightly, or the second protruding portion of the second solar tile structure is wedged with the corresponding first sunken portion of the first solar tile structure tightly when the second solar tile structure is connected to the first solar tile structure.

11. The solar tile structure combination of claim 10, wherein the first protruding portion of the first base and the second protruding portion of the second base are resilient hooks respectively, and the first sunken portion of the first base and the second sunken portion of the second base are slots corresponding to the resilient hooks respectively.

12. The solar tile structure combination of claim 10, wherein the first short side of the first base is parallel to the second short side substantially, and the third short side of the second base is parallel to the fourth short side substantially.

13. The solar tile structure combination of claim 10, wherein a rim is formed on a first long side of the first base.

14. The solar tile structure combination of claim 13 further comprising:
a third solar tile structure comprising:
a third solar panel; and
a third base, an upper surface of the third base being for supporting the third solar panel, a third protruding portion being formed on a lateral surface of a fifth short side of the third base, a third sunken portion being formed on a lateral surface of a sixth short side of the third base, and the third protruding portion of the fifth short side and the third sunken portion of the sixth short side being structural portions capable of wedging with each other tightly;
wherein the sixth short side of the third base and a lateral side of the third protruding portion substantially align with two lateral sides of the third solar panel, and a rim is formed on a fifth long side of the third base.

15. The solar tile structure combination of claim 14, wherein the fifth long side of the third base aligns with the first long side of the first base substantially.

16. The solar tile structure combination of claim 13, wherein lateral surfaces of the first long side and the second long side of the first base are horizontal surfaces respectively.

17. The solar tile structure combination of claim 13, wherein the first long side of the first base is parallel to the second long side substantially.

18. The solar tile structure combination of claim 13, wherein the first solar tile structure further comprises a plurality of buffers disposed on the lateral surfaces of the first short side and the second short side of the first base respectively.

19. The solar tile structure combination of claim 13, wherein the first solar tile structure further comprising:
a junction box disposed on a bottom surface of the first base; and
a transmission cable, two ends of the transmission cable being electrically connected to the first solar panel and the junction box for transmitting electricity transformed by the first solar panel to the junction box.

20. The solar tile structure combination of claim 19, wherein the first solar tile structure further comprises:
a battery module electrically connected to the junction box for storing the electricity received by the junction box.
